(19) United States
(12) Patent Application Publication
(10) Pub. No.: US 2007/0254434 A1
(43) Pub. Date: Nov. 1, 2007

(54) Semiconductor device and manufacturing method thereof

(75) Inventors: Ichiro Mizushima, Yokohama-shi (JP); Yoshio Ozawa, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/819,428

(22) Filed: Jun. 27, 2007

Related U.S. Application Data
(62) Division of application No. 11/315,280, filed on Dec. 23, 2005.

(30) Foreign Application Priority Data
Dec. 27, 2004 (JP) 2004-377295

(51) Int. Cl. H01L 21/336

(52) U.S. Cl. 438/257; 257/E21.409

(57) ABSTRACT

A semiconductor device includes a semiconductor substrate including an active area (AA) surrounded by an isolation insulating film, and a nonvolatile memory cell on the AA, the nonvolatile memory cell including a tunnel insulating film on the AA, a FG electrode on the tunnel insulating film, a CG electrode above the FG electrode, and an interelectrode insulating film between the FG electrode and the CG electrode, relating to a cross section in a channel width direction of the nonvolatile memory cell, dimension in the channel width direction of a top surface of the AA is shorter than dimension in the channel width direction of a bottom surface of the tunnel insulating film, and an area of a portion opposing the AA of the tunnel insulating film is smaller than an area of a portion opposing a top surface of the FG electrode of the interelectrode insulating film.

### CROSS-REFERENCE TO RELATED APPLICATIONS

This application is based upon and claims the benefit of priority from prior Japanese Patent Application No. 2004-377295, filed Dec. 27, 2004, the entire contents of which are incorporated herein by reference.

### BACKGROUND OF THE INVENTION

1. Field of the Invention

The present invention relates to a semiconductor device comprising a nonvolatile memory cell including a floating gate electrode and a control gate electrode, and a method of manufacturing the same.

2. Description of the Related Art

As one of the semiconductor memory devices, there is a nonvolatile semiconductor memory. In recent years, the nonvolatile semiconductor memory has been demanded highly as a device for data storage. As a typical electrically rewritable nonvolatile memory using the floating gate electrode, NOR type flash memory and NAND type flash memory have been well known.

FIG. 18 shows a sectional view of the memory cell of a conventional NAND type flash memory. FIG. 18 shows a sectional view taken along word line (channel width direction) (Jpn. Pat. Appln. KOKAI Publication No. 8-316348). In FIG. 18, reference numeral 81 denotes a silicon substrate, reference numeral 81AA denotes an active area, reference numeral 82 denotes an isolation insulating film, reference numeral 83 denotes a tunnel insulating film (thermal oxide film), reference numeral 84 denotes a floating gate electrode (polycrystalline silicon layer), reference numeral 85 denotes an interelectrode insulating film (inter-poly dielectric layer) and reference numeral 86 denotes a control gate electrode.

The active area 81AA, tunnel insulating film 83 and floating gate electrode 84 are formed as follows. First, the thermal oxidize film and the polycrystalline silicon layer are formed on the silicon substrate 81 sequentially. Next, a resist pattern is formed on the polycrystalline silicon layer. Thereafter, with the resist pattern as a mask, the polycrystalline silicon layer, the thermally-oxidized film and the silicon substrate 81 are etched sequentially by dry process. As a result, the active area 81AA, the tunnel insulating film 83 and the floating gate electrode 84 are formed in a self-align manner. Thus, the area of the top surface of the tunnel insulating film 83 and the area of the bottom surface of the floating gate electrode 84 become equal.

To increase the memory capacity of NAND type flash memory, miniaturization of elements has been developed. As a consequence, such a problem in difficulty of securing a coupling ratio (C2/(C1+C2)) has become prominent. C2 is a coupling capacitance between the control gate electrode and floating gate electrode. C1 is a coupling capacitance between the floating gate electrode and the substrate

In the memory cell shown in FIG. 18, the areas of the tunnel insulating film 83 and the interelectrode insulating film 85 contributing to the coupling capacities C1, C2 are equal. Therefore, the coupling ratio is determined by dielectric constant and thickness of the tunnel insulating film 83 and the interelectrode insulating film 85.

However, in elements which have been miniaturized to a great extent, it is difficult to thin the interelectrode insulating film 85 in order to increase the coupling ratio. On the other hand, if a high dielectric constant material is used as a material for the interelectrode insulating film 85 to increase the coupling ratio by decreasing the area of interelectrode insulating film, a large electric field is generated in the interelectrode insulating film 85 at the time of writing of data. If such a large electric field is generated in the interelectrode insulating film 85, current density of the interelectrode insulating film 85 increases. As a consequence, a writable largest electric field decreases or electric charge accumulated in the floating gate electrode 84 becomes likely to leak easily through the interelectrode insulating film 85. These can become causes for deterioration of the characteristic of a nonvolatile memory cell.

### BRIEF SUMMARY OF THE INVENTION

According to an aspect of the present invention, there is provided a semiconductor device comprising: a semiconductor substrate including an active area surrounded by an isolation insulating film; and a nonvolatile memory cell provided on the active area, the nonvolatile memory cell including a tunnel insulating film provided on the active area, a floating gate electrode provided on the tunnel insulating film, a control gate electrode provided above the floating gate electrode, and an interelectrode insulating film provided between the floating gate electrode and the control gate electrode, relating to a cross section in a channel width direction of the nonvolatile memory cell, dimension in the channel width direction of a top surface of the active area is shorter than dimension in the channel width direction of a bottom surface of the tunnel insulating film, and an area of a portion opposing the active area of the tunnel insulating film is smaller than an area of a portion opposing a top surface of the floating gate electrode of the interelectrode insulating film.

According to an aspect of the present invention, there is provided a method of manufacturing a semiconductor device comprising a semiconductor substrate including an active area surrounded by an isolation insulating film, a nonvolatile memory cell provided on the active area, the method comprising: forming a first insulating film as a tunnel insulating film and a first conductive film as a floating gate electrode sequentially on the semiconductor substrate; forming an isolation trench on a surface of the semiconductor substrate defining the active area and shapes of the floating gate electrode and the tunnel insulating film in a channel width direction of the nonvolatile memory cell by etching the first conductive film, the first insulating film and the semiconductor substrate, the isolation trench being formed such that relating to a cross section in the channel width direction of the nonvolatile memory cell, dimension of a top surface of the active area is shorter than dimension of a bottom surface of the tunnel insulating film; forming the isolation insulating film in the isolation trench; forming a second insulating film as interelectrode insulating film and a second conductive film as a control gate electrode on the first conductive film sequentially; and determining shapes of the control gate electrode, the interelectrode insulating film, the floating gate electrode and the tunnel insulating film by etching the second conductive film, the second insulating film, the first conductive film and the first insulating film sequentially.

### BRIEF DESCRIPTION OF THE SEVERAL VIEWS OF THE DRAWING

FIG. 1 is a plane view showing a memory cell according to a first embodiment of the present invention;

FIG. 2 is a diagram of an equivalent circuit of the memory cell of FIG. 1;

FIG. 3A is a sectional view taken along the line A-A′ of FIG. 1, and FIG. 3B is a sectional view taken along the line B-B′;

FIGS. 4A and 4B are sectional views showing steps of a method of manufacturing the memory cell according to the first embodiment of the invention;

FIGS. 5A and 5B are sectional views showing steps of the method of manufacturing the memory cell according to the first embodiment of the invention following FIGS. 4A and 4B;

FIGS. 6A and 6B are sectional views showing steps of the method of manufacturing the memory cell according to the first embodiment of the invention following FIGS. 5A and 5B;

FIGS. 7A and 7B are sectional views showing steps of the method of manufacturing the memory cell according to the first embodiment of the invention following FIGS. 6A and 6B;

FIGS. 8A and 8B are sectional views showing steps of the method of manufacturing the memory cell according to the first embodiment of the invention following FIGS. 7A and 7B;

FIGS. 9A and 9B are sectional views showing steps of the method of manufacturing the memory cell according to the first embodiment of the invention following FIGS. 8A and 8B;

FIGS. 10A and 10B are sectional views showing steps of the method of manufacturing the memory cell according to the first embodiment of the invention following FIGS. 9A and 9B;

FIGS. 11A and 11B are sectional views showing steps of the method of manufacturing the memory cell according to the first embodiment of the invention following FIGS. 10A and 10B;

FIGS. 12A and 12B are sectional views showing steps of the method of manufacturing the memory cell according to the first embodiment of the invention following FIGS. 11A and 11B;

FIG. 13 is a sectional view showing a memory cell according to a second embodiment of the present invention;

FIG. 14 is a sectional view showing a memory cell according to a third embodiment of the present invention;

FIG. 15 is a sectional view showing a memory cell according to another embodiment of the present invention;

FIG. 16 is a sectional view showing a memory cell according to still another embodiment of the present invention;

FIG. 17 is a sectional view showing a conventional memory cell; and

FIG. 18 is a sectional view showing a conventional memory cell.

### DETAILED DESCRIPTION OF THE INVENTION

Hereinafter, embodiments of the present invention will be described with reference to the accompanying drawings.

### First Embodiment

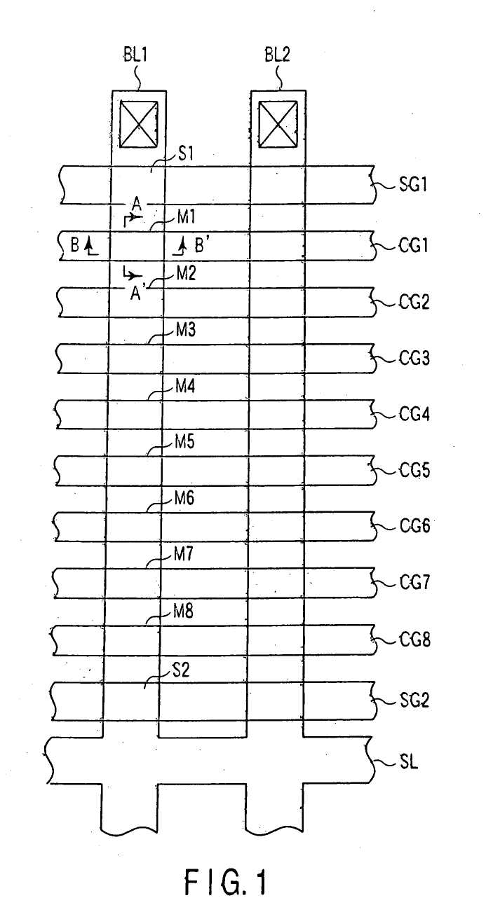

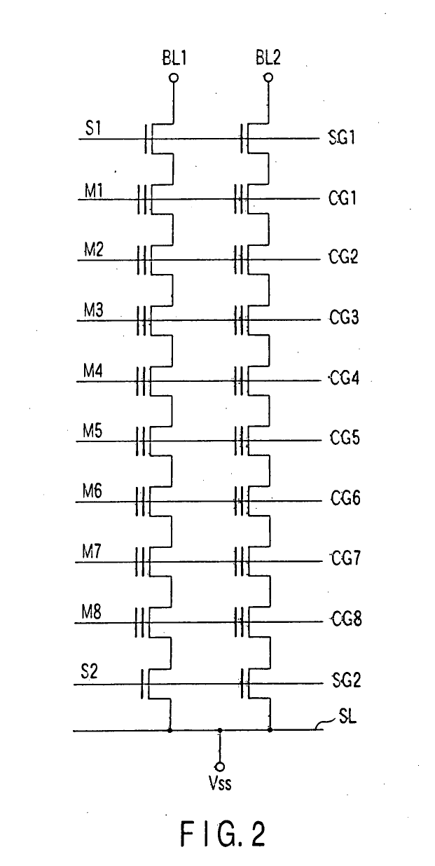

FIG. 1 is a plane view showing a memory cell according to a first embodiment of the present invention. FIG. 2 is a diagram of an equivalent circuit of the memory cell of FIG. 1. In FIGS. 1 and 2, M1 to M8 each denote a nonvolatile memory cell portion, S1 and S2 each denote a selective transistor portion, CG1 to CG8 denote floating gates (word lines), SG1 and SG2 denote selective gates, BL1 and BL2 denote bit lines, SL denotes a source line, and Vss denotes a power supply voltage (ground).

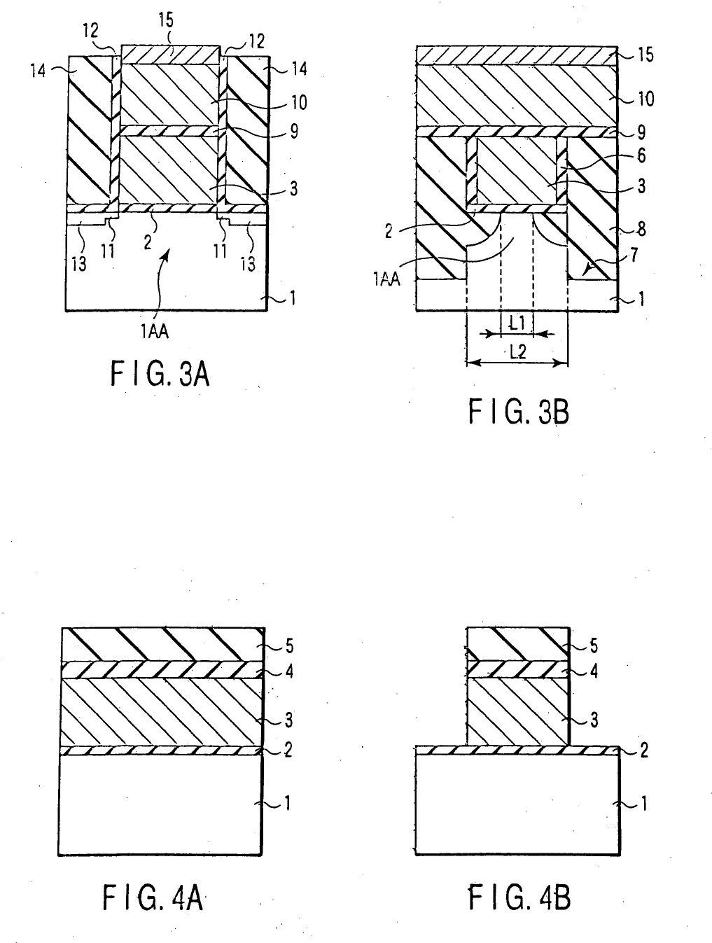

FIG. 3A is a sectional view taken along the line A-A′ of FIG. 1, namely shows a sectional view along bit line (channel length direction). FIG. 3B is a sectional view taken along the line B-B′, namely, shows a sectional view along word line direction (channel width direction).

In the figures, reference numeral 1 denotes a silicon substrate, 1AA denotes an active area, 2 denotes a tunnel insulating film, 3 denotes a floating gate electrode, 6 denotes a first side wall insulating film, 7 denotes an isolation trench, 8 denotes an isolation insulating film, 9 denotes an interelectrode insulating film, 10 denotes a control gate electrode, 11 denotes an extension, 12 denotes a second side wall insulating film, 13 denotes a source/drain area, 14 denotes an interlayer insulating film, and 15 denotes a cobalt silicide film.

The NAND type flash memory of the present embodiment comprises the silicon substrate 1 including the active area 1AA whose periphery is surrounded by the isolation insulating film 8 and a memory cell provided on the active area 1AA.

The memory cell includes the tunnel insulating film 2 provided on the active area 1AA, the floating gate electrode 3 provided on the tunnel insulating film 2, the control gate electrode 10 provided above the floating gate electrode 3, and the interelectrode insulating film 9 provided between the floating gate electrode 3 and the control gate electrode 10.

In the cross section in the word line direction (channel width direction) of the memory cell, a dimension L1 in the channel width direction of the top surface of the active area 1AA is shorter than a dimension L2 in the channel width direction of the bottom surface of the tunnel insulating film 2. The area (S1) of a portion opposing the active area 1AA of the tunnel insulating film 2 is smaller than the area (S2) of a portion opposing the top surface of the floating gate electrode 3 of the interelectrode insulating film 9. The dimensions in the channel width direction of the top surface and bottom surface of the floating gate electrode 3 are almost the same.

According to the present embodiment, the area S1 of the tunnel insulating film 2 is smaller than the area S2 of the interelectrode insulating film 9. Therefore, the area S1 of the tunnel insulating film 2 and the area S2 of the interelectrode insulating film 9 as well as the dielectric constant and thickness of the tunnel insulating film 2 and the dielectric constant and thickness of the interelectrode insulating film 9 act as parameter which affects the coupling ratio.

If the dielectric constant and thickness of the tunnel insulating film 2 and the dielectric constant and the thickness of the interelectrode insulating film 9 are set to the same ones as a conventional memory, the coupling ratio increases because S1<S2.

On the other hand, if the coupling ratio is set to the same one as that of the conventional memory, the thickness of the interelectrode insulating film 9 can be increased. If the thickness of the interelectrode insulating film 9 increases, an electric field (current density) generated in the interelectrode insulating film 9 decreases. For example, if the thickness of the tunnel insulating film 2 is ⅓ the thickness of the interelectrode insulating film 9, the thickness of the interelectrode insulating film 9 can be increased by three times. Thereby, the electric field generated in the interelectrode insulating film 9 becomes ⅓. In this way, even if an insulating film including a high dielectric constant material is used as the interelectrode insulating film 9, generation (deterioration of characteristic) of leak current passing through the interelectrode insulating film 9 can be suppressed by thickening the interelectrode insulating film 9. By suppressing generation of leak current, operating current for write/erase is reduced.

Thus, because S1>S2 is achieved according to the present embodiment, the NAND type flash memory capable of suppressing deterioration of the characteristic and increasing the coupling ratio can be achieved by selecting the thickness of the tunnel insulating film 2 and the thickness of the interelectrode insulating film 9 appropriately even if insulation layer including the high dielectric constant material is used as the interelectrode insulating film 9.

Next, a method of manufacturing the NAND flash memory of the present embodiment will be described with reference to FIGS. 4A and 4B to 12A and 12B. “A” in each figure is a sectional view taken along the line A-A′ of FIG. 1A and “B” in each figure is a sectional view taken along the line B-B′ of FIG. 1A.

First, as shown in. FIGS. 4A and 4B, the tunnel insulating film 2 is formed by thermal oxidation method on the surface of the silicon substrate 1 doped with a desired impurity. The thickness of the tunnel insulating film 2 is, for example, 10 nm.

Next, the polycrystalline silicon layer 3 to be processed into the floating gate electrode, the stopper film 4 for chemical mechanical polish (CMP) and the mask film 5 for reactive ion etched (RIE) are deposited sequentially by low pressure chemical vapor deposition (LPCVD). The thickness of the polycrystalline silicon layer 4 is, for example, 150 nm.

Next, the mask film 5, the stopper film 4, the polycrystalline silicon film 3 and the tunnel insulating film 2 are etched sequentially by RIE process using resist mask (not shown). As a result, the shapes of the tunnel insulating film 2 and the floating gate electrode (polycrystalline silicon layer 3) in the bit line direction are determined.

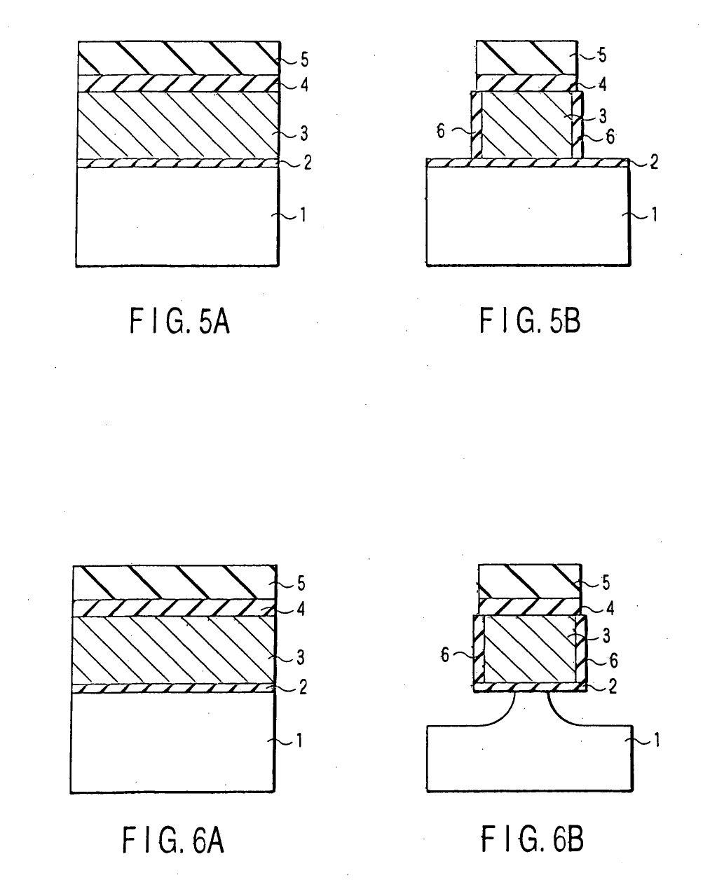

Next as shown in FIGS. 5A and 5B, the first side wall insulating film 6 is formed on the side wall of the polycrystalline silicon layer 3 by thermal oxidation method.

Next, as shown in FIGS. 6A and 6B, an area of the tunnel insulating film whose surface is exposed is etched selectively by some kinds of dry etching process. Thereafter, the silicon substrate 1 is etched isotropically by well known down flow process, which is one of etching methods by using mixture gas of CF₄ and oxygen in gaseous phase using radical. In such etching, the silicon substrate 1 is etched isotropically by heating or cooling the silicon substrate 1 at a predetermined temperature of 0 to 700° C. and next flowing CF₄ gas at a rate of 1 to 500 cc/min, so that a recessed trench as shown in FIG. 6B is formed. The gas for use is not restricted to CF₄ and it is permissible to use mixture gas including CF₄ and O₂ gas or gas including other halogen.

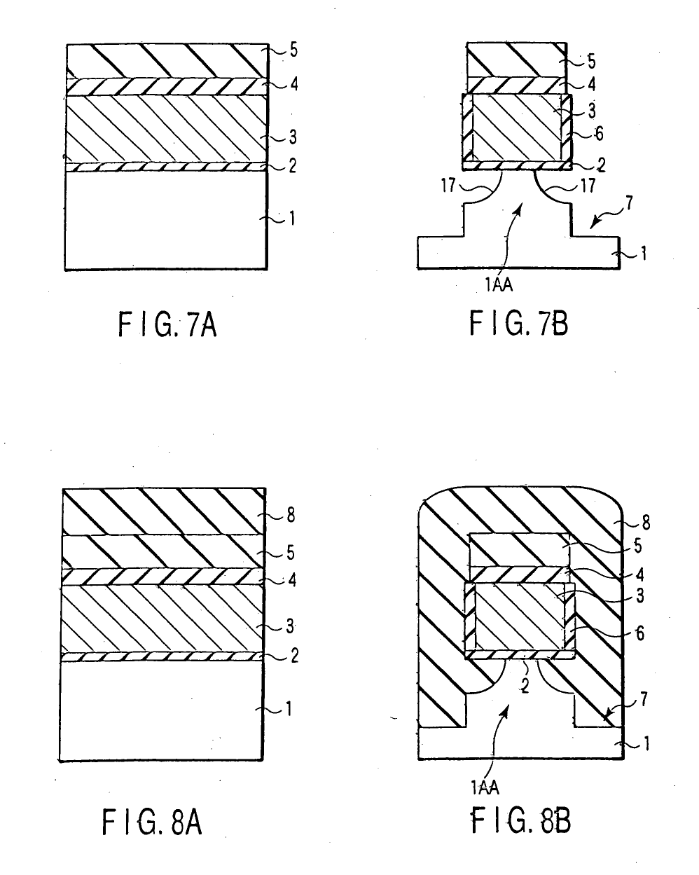

Next, as shown in FIGS. 7A and 7B, the exposed area of the silicon substrate 1 is etched anisotropically by RIE process, so that the isolation trench 7 is formed. The depth of the isolation trench 7 is, for example, 150 nm. Further, the shape of the active area 1AA is determined. That is, the active area 1AA including a structure in which the dimension in the channel width direction of a portion opposing the tunnel insulating film 2 increases as it goes downward is obtained. The side surface of the portion whose dimension in the channel width direction increases includes a convex surface 17 downward.

Next, as shown in FIGS. 8A and 8B, a silicon oxide film (not shown) is formed on the exposed surface (bottom surface and side face of the isolation trench 7) of the silicon substrate 1 by thermal oxidation method, thereafter, the isolation insulating film 8 is deposited such that the isolation trench 7 is filled by plasma CVD process. Here, the silicon oxide film is used as the isolation insulating film 8. The thickness of the thermal silicon oxide film (not shown) is, for example, 5 nm, and the thickness of the isolation insulating film 8 is, for example, 400 nm.

To fill the trench area formed by etching in a lateral direction by the down flow process of the isolation trench 7 in the step of FIGS. 6A and 6B, with isolation insulating film effectively, a following method may be used.

That is, the inside of the isolation trench 7 is filled with an insulating film including a silicon oxide film formed by a plasma CVD process and a silicon oxide film (coating film) formed by a coating method (or silicon oxide film formed by a thermal CVD process).

More specifically, the trench area of the isolation trench 7 formed by the RIE process in the step of FIGS. 7A and 7B is filled with the isolation insulating film 8, thereafter, the other trench area is filled with the silicon oxide film (coating film) formed by the coating method or the silicon oxide film formed by the thermal CVD process.

Next, the top portion of the isolation insulating film 8 and the mask film 5 are removed by CMP process such that the stopper film 4 is exposed and the surface is flatten.

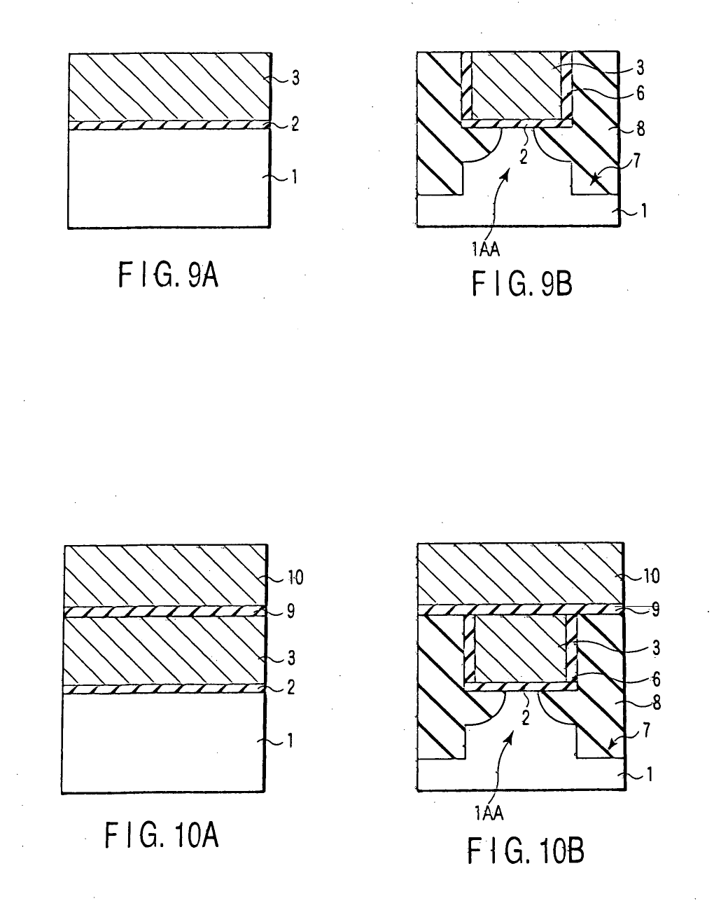

Next, the isolation insulating film 8 is etched by only an amount corresponding to the thickness of the stopper film 4 with hydrofluoric acid, and further, as shown in FIGS. 9A and 9B, the exposed stopper film 4 is removed with a phosphoric acid solution.

As a result, the height of top surface of the isolation insulating film 8 and the height of the top surface of the polycrystalline silicon layer 3 turn to almost the same level. Further, the isolation insulating film 8 surrounding the periphery of the active area 1AA comes to surround the periphery of the tunnel insulating film 2 and the floating gate electrode 3.

Next, as shown in FIGS. 10A and 10B, a high dielectric constant insulating film to be processed into the interelectrode insulating film 9 is deposited on an entire surface by atomic layer chemical vapor deposition (ALCVD) process, thereafter, a polycrystalline silicon layer doped with phosphor to be processed into the control gate electrode 10 is deposited on the high dielectric constant insulating film.

The high dielectric constant insulating film is an insulating film having dielectric constant of 6.0 or greater. More specifically, a monolayer or multilayer insulating film having at least one of silicon nitride, aluminum oxide, hafnium oxide, tatalum oxide, titan oxide and silicate can be used. Here, as the high dielectric constant insulating film, an alumina film having a thickness of 15 nm is used.

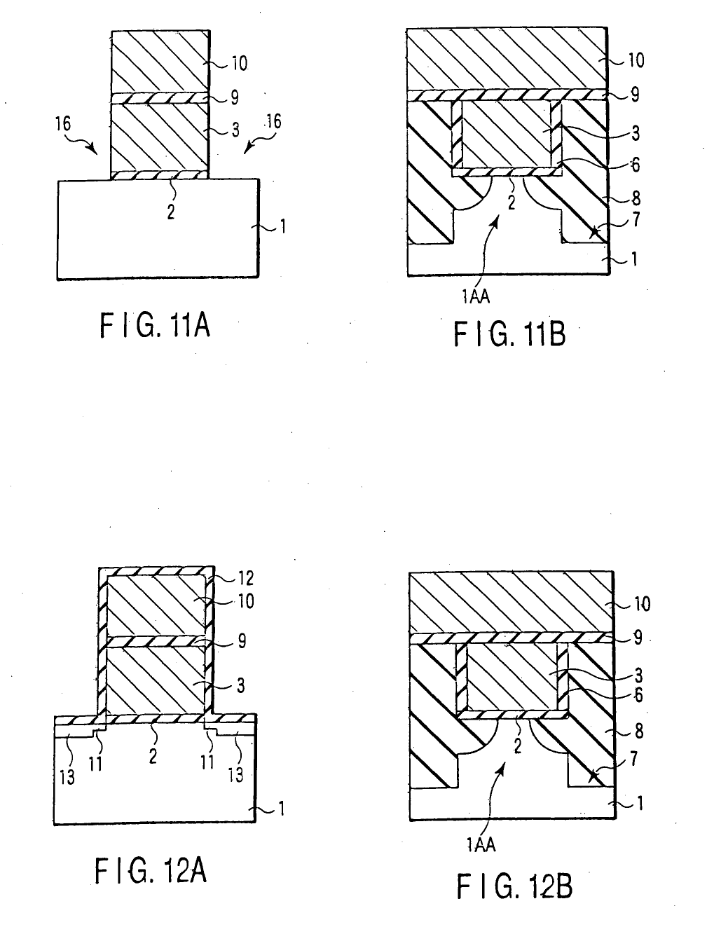

Next, as shown in FIGS. 11A and 11B, a mask film (not shown) and a resist pattern (not shown) are formed sequentially on the polycrystalline silicon layer, thereafter, with the resist pattern used as a mask, the mask film is etched by RIE process, further, with the resist pattern and the mask used as a mask, the polycrystalline silicon layer, the high dielectric constant insulating film, the polycrystalline silicon film 3 and the tunnel insulating film 2 are etched sequentially by RIE process.

As a result, a slit portion 16 is formed in part of the control gate electrode and between adjoining memory cells in the bit line direction. The shapes of the control gate electrode 10, the interelectrode insulating film 9, the floating gate electrode 3 and the tunnel insulating film 2 are determined by the slit portion 16.

Next, as shown in FIGS. 12A and 12B, the extension 11 is formed on the surface of the silicon substrate 1 using ion implantation process and annealing process.

Next, the silicon oxide film 12 is formed on the surface (top surface and side face) of the gate portion (tunnel insulating film 2, floating gate electrode 3, interelectrode insulating film 9, control gate electrode 10) and the exposed surface of the silicon substrate 1 by thermal oxidation method and LPCVD process. The thickness of the silicon oxide film 12 is, for example, 10 nm. Such an insulating film as the silicon oxide film 12 is called an electrode side wall insulating film (spacer).

Next, the source/drain area 13 is formed on the surface of the silicon substrate 1 by using ion implantation process and anneal process again.

Next, a BPSG (borophosphosilicate glass) film to be processed into the interlayer insulating film 14 is deposited on the entire surface by LPCVD process, thereafter, the BPSG film and the silicon oxide film 12 are polished by CMP process until the top surface of the control gate electrode 10 is exposed.

Next, a Co film and a TiN film are deposited sequentially on the entire surface by sputtering process, thereafter, reaction of Si and Co to cobalt silicide (CoSi₂) is induced on the top surface of the control gate electrode (polycrystalline silicon film) 10 by RTA process, subsequently, the TiN film and unreacted Co film are removed by chemical treatment. As a consequence, the cobalt silicide film 15 is formed on the top surface of the control gate electrode 10. Any metal silicide film other than the cobalt silicide film 15 may be formed. In this way, the memory cell shown in FIGS. 3A and 3B is obtained.

Thereafter, known steps such as formation step of the wiring layer are carried out and the NAND flash memory is obtained.

As described above, according to the present embodiment, a novel cell structure is introduced, so that the coupling ratio of the cell can be increased while suppressing the deterioration of the characteristic. By increasing the coupling ratio, the electric field generated in the interelectrode insulating film 9 can be reduced, and consequently, the operation voltage is reduced.

### Second Embodiment

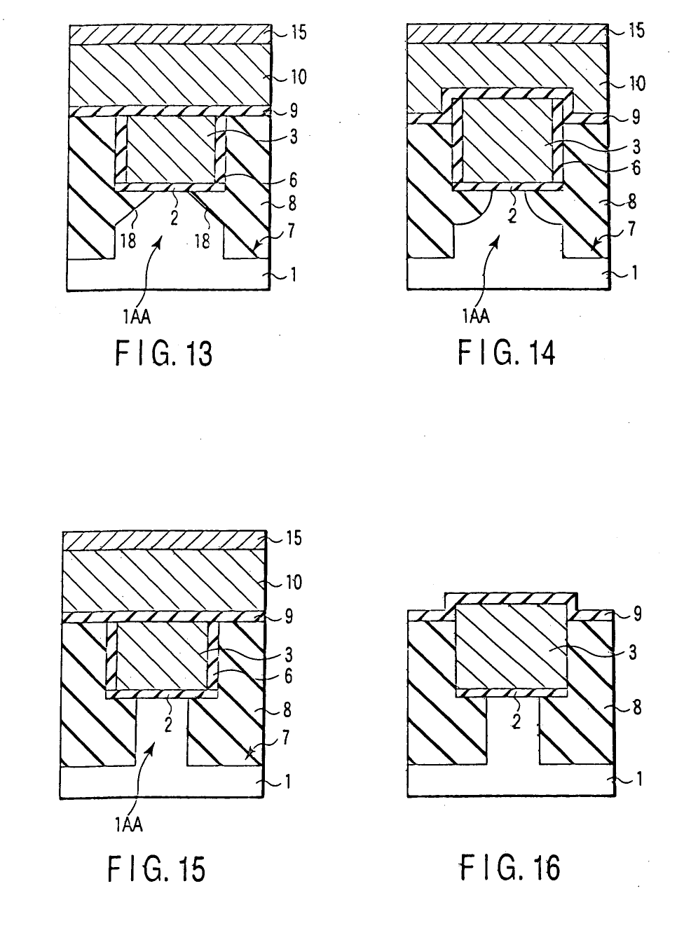

FIG. 13 is a sectional view showing a memory cell according to a second embodiment of the present invention. FIG. 13 is a sectional view in the channel width direction corresponding to FIG. 3B. In the meantime, the same reference numerals as FIG. 3B are attached to portions corresponding to FIG. 3B, and a detailed description thereof is not repeated.

The present embodiment is different from the first embodiment in that the side surface of the active area 1AA of a portion opposing the tunnel insulating film 2 includes a substantially flat surface 18.

Such a structure is obtained by etching the silicon substrate 1 isotropically by using etchant which increases the etching rate of Si with respect to SiO₂ instead of down flow process, for example, wet process (wet etching) using KOH in the step of FIG. 6 of the first embodiment.

This is because in case of the wet process using KOH, the etching surface has an inclination dependent on crystalline plane such as (111) plane and (110) plane. If the main surface of the silicon substrate 1 is (100) plane and it orientation is <010>, the orientation of the flat surface is <101>.

Even in case of the above-described structure, the coupling ratio increases like the first embodiment. Accordingly, the electric field generated in the interelectrode insulating film 9 is reduced, so that the same effect as the first embodiment is obtained.

### Third Embodiment

FIG. 14 is a sectional view showing a memory cell according to a third embodiment of the present 25 invention. FIG. 14 is a sectional view in the channel width direction corresponding to FIG. 3B. The same reference numerals as FIG. 3B are attached to portions corresponding to FIG. 3B, and detailed description thereof is not repeated.

The present embodiment is different from the first embodiment in that the interelectrode-insulating film 9 is further provided in the channel width direction on the side surface of the top portion of the floating gate electrode 3 as well.

Such a structure is obtained by increasing the etching amount of the isolation insulating film 8 by a hydrofluoric acid solution so as to expose the side surface of the top portion of the floating gate electrode 3 in the step of FIG. 9 of the first embodiment.

According to the structure, an opposing area between the floating gate electrode 3 and the interelectrode insulating film 9 is larger than that of the first embodiment, so that the coupling ratio can be increased further.

To achieve the above structure, it is necessary to increase the thickness of the floating gate electrode 3. For the reason, the size of the side surface of the top portion of the exposed floating gate electrode 3 needs to be determined by considering the electric characteristic (electric interference between cells) of the memory cell and the RIE process of FIG. 11.

The present invention is not limited to the above described embodiments. For example, in the embodiments, a case where a silicon substrate is used as the semiconductor substrate has been described, other semiconductor substrates may be used. For example, it is permissible to use a SOI substrate or a semiconductor substrate including a SiGe area in its active area.

Further, the present invention can be applied to a semiconductor device (embedded LSI) including a flash memory and logic circuit.

Further, in the embodiments, only the top surface side of the active area 1AA in the channel width direction is shorter than the tunnel insulating film, the entire active area 1AA may be shorter than the tunnel insulating film as shown in FIG. 15.

Further, as shown in FIG. 16, the interelectrode insulating film 9 is not necessary flat. Moreover, as shown in FIG. 16, the first side wall insulating film 6 may be absent.

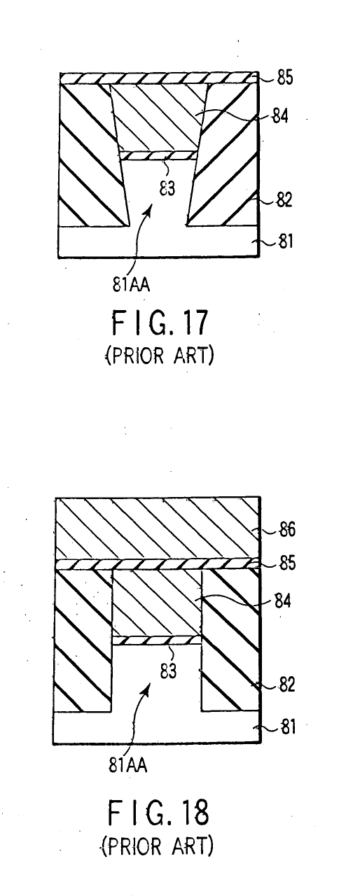

Further, the structure shown in FIG. 17 (FIG. 14 in Jpn. Pat. Appln. KOKAI Publication No. 8-316348) has such a feature that the area of a tunnel insulating film 83 at a portion opposing the active area 1AA is smaller than the area of an interelectrode insulating film 85 at a portion opposing the top surface of a floating gate electrode 84, the embodiments of the invention have an advantage in terms of device characteristic in the following points.

One of the points is that the breakdown voltage of edge of the tunnel insulating film is high. The reason is as follows. In the structure of FIG. 17, the edge of an active area 1AA and an edge of the floating gate electrode 84 are located at the same position as the tunnel insulating film 83, so that leak current is likely to occur at this portion.

On the other hand, in the present invention, end portions of the active area 1AA are located inside end portions of the floating gate electrode 3, the breakdown voltage at this position is excellent. Another point is that the formation of an edge channel is suppressed by the present invention. According to the structure of the present invention, the floating gate electrode 3 exists to cover both sides of the channel edge. Therefore, electric field control performance on the channel edge area from the floating gate electrode is strengthened. Thereby, the formation of the edge channel is suppressed.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1-10. (canceled)

11. A method of manufacturing a semiconductor device comprising a semiconductor substrate including an active area surrounded by an isolation insulating film, a nonvolatile memory cell provided on the active area, the method comprising:
forming a first insulting film as a tunnel insulating film and a first conductive film as a floating gate electrode sequentially on the semiconductor substrate;
forming an isolation trench on a surface of the semiconductor substrate defining the active area and shapes of the floating gate electrode and the tunnel insulating film in a channel width direction of the nonvolatile memory cell by etching the first conductive film, the first insulating film and the semiconductor substrate, the isolation trench being formed such that elating to a cross section in the channel width direction of the nonvolatile memory cell, dimension of a top surface of the active area is shorter than dimension of a bottom surface of the tunnel insulating film;
forming the isolation insulating film in the isolation trench;
forming a second insulating film as interelectrode insulating film and a second conductive film as a control gate electrode on the first conductive film sequentially; and
determining shapes of the control gate electrode, the interelectrode insulating film, the floating gate electrode and the tunnel insulating film by etching the second conductive film, the second insulating film, the first conductive film and the first insulating film sequentially.

12. The manufacturing method according to claim 11,
wherein the forming the isolation trench includes etching the first conductive film, the first insulating film and the semiconductor substrate isotropically, and etching the semiconductor substrate anisotropically.

13. The manufacturing method according to claim 12,
wherein the etching the semiconductor substrate isotropically includes etching in gaseous phase.

14. The manufacturing method according to claim 12,
wherein the etching the semiconductor substrate isotropically includes etching with solution.

15. The manufacturing method according to claim 11,
wherein the forming the isolation insulating film in the isolation trench includes forming a first isolation insulating film by CVD process, and forming a second isolation insulating film on the first isolation insulating film by coating method.

16. The manufacturing method according to claim 15,
wherein the first isolation insulating film and the second isolation insulating film are insulating films of same kind.

17. The manufacturing method according to claim 12,
wherein the forming the isolation insulating film within the isolation trench includes forming a first isolation insulating film by CVD process, and forming a second isolation insulating film on the first isolation insulating film by coating method.

18. The manufacturing method according to claim 17,
wherein the first isolation insulating film and the second isolation insulating film are insulating films of same kind.

19. The manufacturing method according to claim 13,
wherein the forming the isolation insulating film within the isolation trench includes forming a first isolation insulating film by CVD process, and forming a second isolation insulating film on the first isolation insulating film by coating method.

20. The manufacturing method according to claim 19,
wherein the first isolation insulating film and the second isolation insulating film are insulating films of same kind.
